(19) United States
(12) Patent Application Publication
(10) Pub. No.: US 2010/0110159 A1
(43) Pub. Date: May 6, 2010

(54) IMAGE READING DEVICE AND IMAGE FORMING APPARATUS

(75) Inventors: Masuo Kawamoto, Osaka (JP); Hiroshi Ito, Osaka (JP)

Correspondence Address: K&L Gates LLP, P.O. Box 1135, CHICAGO, IL, 60690, US

(73) Assignee: KYOCERA MITA CORPORATION, Osaka (JP)

(21) Appl. No.: 12/554,283

(22) Filed: Sep. 4, 2009

(30) Foreign Application Priority Data
Oct. 31, 2008 (JP) 2008-281140

(51) Int. Cl. B41J 2/435; H05K 5/00

(52) U.S. Cl. 347/224; 361/679.01

(57) ABSTRACT

An image reading device having a recessed part which is located at a backward end with respect to a home-position of an image reading unit and extending downwardly with respect to a flat surface. When the image reading unit is located in the home-position, the recessed part receives a bent part of a flexible flat cable. With the image reading device, an upward pushing force applied to the image reading unit because of a repulsive force generated by the flexible flat cable trying to straighten itself is reduced.

### INCORPORATION BY REFERENCE

This application is based upon and claims the benefit of priority from the corresponding Japanese Patent Application No. 2008-281140 filed Oct. 31, 2008, the entire contents of which are incorporated herein by reference.

### BACKGROUND

1. Field of the Invention

The present invention relates to image reading devices and image forming apparatuses, and more particularly to the handling of electrical transmission cables in such devices.

2. Description of the Related Art

The present invention relates to image reading devices which reads an image of a document and to image forming apparatuses.

Conventionally, an image reading device, such as a scanner, typically uses a configuration wherein an image of a document that is placed on a document reading surface is read while an image reading unit is moved in a space below the document reading surface.

In such an image reading device, a fixed unit is positioned in a casing. The fixed unit is electrically connected to the image reading unit. The casing supports the document reading surface. The fixed unit is connected to the image reading unit by a cable.

The cable connects the fixed unit to the image reading unit with a part of the cable being bent so that the image reading unit can reciprocate in the space below the document reading surface.

When the cable connects the fixed unit to the image reading unit, with a part of the cable being bent, a force is generated by cable as it tries to straighten itself. Hence, a force is generated in a direction away from the image reading unit and is applied to the connection between the cable and the image reading unit.

Thus, upon long-term use, the cable can be separated from the image reading unit.

In light of this, it is known to provide an image reading device in which a film member is provided at a position close to the connection between the cable and the image reading unit. The film member prevents the cable from being bent.

Using the film member, the force that is applied to the connection between the cable and the image reading unit in the direction away from the image reading unit can be resisted. The cable can thereby be prevented from separating from the image reading unit.

However, the repulsive force that is generated by the cable trying to straighten itself acts as a force that pushes the image reading unit upwardly. When the image reading unit is pushed upwardly, the image reading unit may be inclined or vertically moved, and the image reading unit therefore may not move smoothly. The force necessary for moving the image reading unit may therefore have to be increased, or a fixing member for fixing the image reading unit may also be additionally necessary.

The bent part of the cable typically is located at a back end of the direction of reciprocation of the image reading unit with respect to the image reading unit. When the image reading unit is located in a home-position wherein the image reading unit is positioned at the most backward end, the cable is located at a position closest to the image reading unit.

The image reading unit receives a greater upwardly pushing force as the image reading unit is closer to the bent part of the cable. Hence, in the typical image reading device, when the image reading unit is located in the home-position, a problem, such as a need to increase the driving force for moving the image reading unit, likely may occur.

### SUMMARY

The present invention provides an image reading device which reduces the upward pushing force that is applied to an image reading unit because of the repulsive force generated by a cable trying to straighten itself.

The present invention provides an image reading device that is capable of reducing the repelling force generated by the cable trying to straighten itself out.

According to an embodiment of the present invention, the image forming apparatus includes a control section designed to control the entire image forming apparatus, a display operation section designed to perform an operation based on the operation of a user, an image storage unit designed to record image data read by an image reading unit and output the read image data, an image processing unit designed to convert the image data input from the image storage unit into print-format image data and output the print-format image data based on the control instruction input from the control section, a print section designed to perform printing on a fed recording sheet based on the control instruction inputted from the control section, and an image reading device fixed to a casing. The image reading device includes the image reading unit having a home-position, a casing supporting the image reading surface such that the image reading surface defines an upper surface of the casing, reciprocating parallel to an image reading surface, and reading an image of a document that is placed on the image reading surface while being moved in a forward direction. A cable is fixed to the casing, arranged above a flat surface of the casing, and connected with the image reading unit and a fixed unit with a part of the cable being bent, the fixed unit is electrically connected with the image reading unit. A recessed part is provided that extends downwardly from the image reading unit and receives the bent part of the cable.

Additional features and advantages are described herein, and will be apparent from the following Detailed Description and the figures.

### BRIEF DESCRIPTION OF THE FIGURES

In the accompanying drawings:

FIG. 1 is a block diagram showing a configuration of a copier including an image reading device according to an embodiment of the present invention;

FIG. 2 is a cross-sectional view showing the configuration of the copier including the image reading device according to an embodiment of the present invention;

FIG. 3 is a perspective view showing the image reading device according to an embodiment of the present invention;

FIG. 4 is a cross-sectional view showing the image reading device according to an embodiment of the present invention;

FIG. 5 is a modification of the image reading device according to an embodiment of the present invention, in particular, is a cross-sectional view showing the image reading device having a configuration in which a recessed part is defined by a plurality of walls; and

FIG. 6 is a modification of the image reading device according to an embodiment of the present invention, in particular, is a cross-sectional view showing the image reading device having a configuration in which a recessed part is formed of a film member.

### DETAILED DESCRIPTION

An image reading device according to an embodiment of the present invention will now be described below with reference to the drawings. In the following drawings, the drawings have been scaled with respect to the elements to illustrate the recognizable sizes of the elements. The following description provides a situation where the image reading device according to an embodiment of the present invention is installed in a copier, which is an example of an image forming apparatus. Also, the cable that is used in the embodiment is a flexible flat cable, however, the cable may be any other cable than a flexible flat cable.

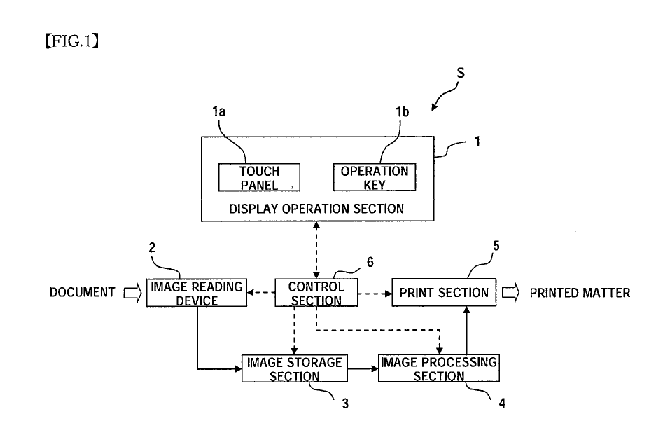

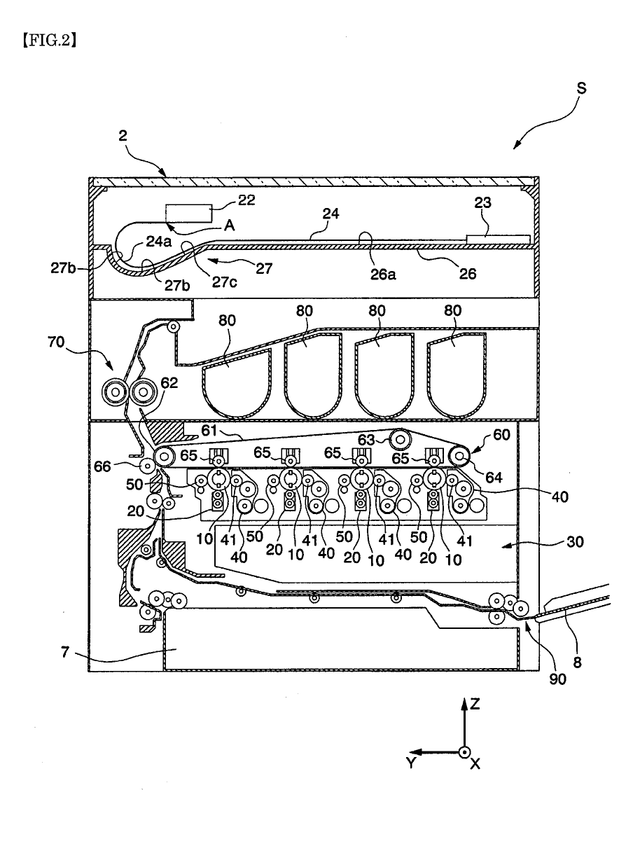

FIG. 1 is a functional block diagram showing a brief design of a copier S including an image reading device 2 of an embodiment. FIG. 2 is a cross-sectional view showing the design of the copier S.

Referring to FIG. 1, the copier S includes a display operation section 1, an image reading device 2, an image storage unit 3, an image processing unit 4, a print section 5, and a control section 6.

The display operation section 1 is positioned on a front surface of the apparatus (not shown in FIG. 2), as an interface which associates the copier S and a user. The display operation section 1 includes a touch panel 1a and an operation key 1b. The touch panel 1a is a display panel having a transparent sheet pressure sensor of, for example, a resistance film type, on a display surface. The touch panel 1a displays information to the user and outputs an operation signal based on the operation of the user. The operation key 1b is an operation key (hardware key), such as a power button or a copy start button, other than an operation button displayed on the touch panel 1a. The operation key 1b outputs an operation signal based on the operation of the user.

The image reading device 2 reads an image of a document which is automatically fed using an auto document feeder (ADF), or of a document which is placed on a document reading surface, with a line sensor, based on a control instruction input from the control section 6, and converts the read image into a document image data. The image reading device 2 outputs the document image data. Referring to FIG. 2, the image reading device 2 is located at an upper part of the copier S. The image reading device 2 will be described in more detail later.

The image storage unit 3 is, for example, a semiconductor memory or a hard disk device. The image storage unit 3 records the document image data input from the image reading device 2, and reads and outputs the document image data recorded therein, based on a control instruction input from the control section 6.

The image processing unit 4 converts the document image data from the image storage unit 3 into print-format image data and outputs the converted image data, based on a control instruction input from the control section 6.

The image processing unit 4 can convert the document image data into print-format image data by applying, as necessary, various image processing to the document image data. For example, when the image reading device 2 reads a document formed of a color image, document image data input from the image storage unit 3 to the image processing unit 4 is RGB image data corresponding to the three primary colors of light. The image processing unit 4 converts the RGB image data into, for example, YMCK image data (image data with basic colors of Y, M, C, and K representing yellow, magenta, cyan, and black), corresponding to the print format of the print section 5. Then, the image processing unit 4 outputs the converted image data.

The print section 5 performs printing (image formation) on a recording sheet (printing medium) fed from a sheet cassette 7 or a sheet feed tray 8 (see FIG. 2) based on a control instruction input from the control section 6. Referring to FIG. 2, the print section 5 is located in a substantially center part of the copier S.

Referring to FIG. 2, the print section 5 includes a photosensitive drum 10, an electrifier 20, a laser scanning unit 30, a development unit 40, a cleaning unit 50, an intermediate transfer unit 60, a fixer 70, and a toner container 80.

The photosensitive drum 10 is a cylindrical member. An electrostatic latent image is formed on the surface of the photosensitive drum 10. The photosensitive drum 10 is positioned to extend in a depth direction of FIG. 2. The copier S is a tandem type image forming apparatus capable of full-color printing. The copier S includes a photosensitive drum 10 for yellow, a photosensitive drum 10 for magenta, a photosensitive drum 10 for cyan, and a photosensitive drum 10 for black, corresponding to the basic colors (Y, M, C, K) of toners. The photosensitive drums 10 are positioned parallel to each other at an interval as shown in FIG. 2.

The electrifier 20 is placed opposite each of the photosensitive drums 10. The electrifier 20 respectively faces each of the photosensitive drums 10 of the basic colors (Y, M, C, K). The electrifier 20 electrifies the circumferential surface of the photosensitive drum 10.

The laser scanning unit 30 is located below the photosensitive drum 10. The laser scanning unit 30 transmits a laser light to irradiate the photosensitive drum 10 with the laser light, and forms an electrostatic latent image on a surface of the photosensitive drum 10.

The development unit 40 includes a development roller 41 which develops an image based on the electrostatic latent image formed on the circumferential surface of the photosensitive drum 10 by supplying the circumferential surface of the photosensitive drum 10 with a toner. A development unit 40 is provided for each of the photosensitive drums 10.

The cleaning unit 50 includes a rubbing roller 51 which removes toner remaining on the photosensitive drum 10 after the image is transferred from the photosensitive drum 10 to the intermediate transfer unit 60. The cleaning unit 50 is located opposite each of the photosensitive drums 10.

The intermediate transfer unit 60 is positioned above the photosensitive drums 10. The intermediate transfer unit 60 includes an intermediate transfer belt 61 on which images developed by the photosensitive drums 10 are transferred, a driving roller 62 for rotating the intermediate transfer belt 61, a tension roller 63 for applying a tensile force to the intermediate transfer belt 61, a driven roller 64 which is rotated by the intermediate transfer belt 61, a primary transfer roller 65 for transferring the toner on the photosensitive drum 10 to the intermediate transfer belt 61, and a secondary transfer roller 66 for transferring toner on the intermediate transfer belt 61 to a recording sheet.

The images developed by the photosensitive drums 10 are temporarily superposed on one another on the intermediate transfer belt 61 of the intermediate transfer unit 60, and then collectively transferred onto a recording sheet. That is, the intermediate transfer unit 60 transfers the toner on the photosensitive drums 10 onto the recording sheet.

The fixer 70 fixes the toner transferred by the intermediate transfer unit 60 onto the recording sheet by applying heat or pressure to the toner. The fixer 70 is located in the feeding path of the recording sheet.

The toner container 80 contains the toner that is supplied to the development unit 40. The toner container 80 is located above the intermediate transfer unit 60. A toner container 80 is provided for each of the development units 40.

A sheet feed roller 90 is provided at a lower part of the apparatus. The sheet feed roller 90 supplies the print section 5 with a recording sheet that is fed from the sheet cassette 7 or the sheet feed tray 8.

Referring back to FIG. 1, the control section 6 controls the entire copier S, and is electrically connected with the display operation section 1, the image reading device 2, the image storage unit 3, the image processing unit 4, and the print section 5.

In the copier S having the above-described design, the image data of the document set at the image reading device 2 is read, and the read image data is recorded in the image storage unit 3, based on operation inputted using the display operation section 1 by the user, under the control of the control section 6. The image processing unit 4 converts the image data recorded in the image storage unit 3 into the print-format image data, and inputs the converted image data to the print section 5.

The print section 5 performs image formation on a printing sheet corresponding to the print-format image data input from the image processing unit 4. Then, the printing sheet, with the image printed thereon, is ejected from the copier S, as printed matter.

Next, an embodiment of the image reading device 2 will be described in more detail.

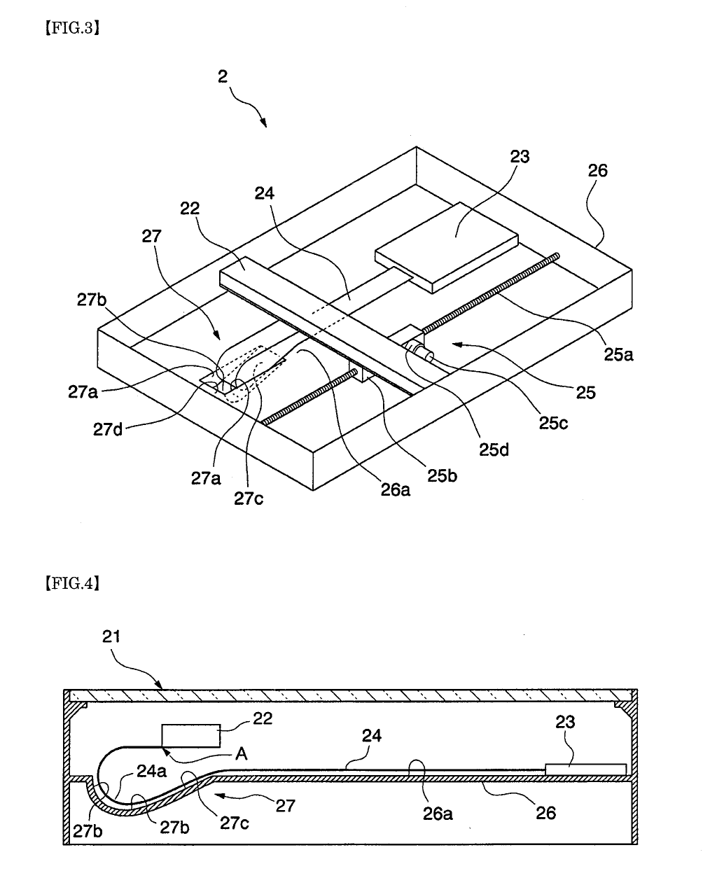

FIG. 3 is an enlarged cross-sectional view showing the image reading device 2. FIG. 4 is a perspective view showing the image reading device 2. Referring to the drawings, the image reading device 2 includes a document reading surface 21, an image reading unit 22, a fixed unit 23, a flexible flat cable 24 (cable), and a moving unit 25.

A document is placed on the document reading surface 21. The document reading surface 21 is supported by a casing 26 of the image reading device 2 such that the document reading surface 21 defines an upper surface of the image reading device 2.

The image reading unit 22 reads the image on the document placed on the document reading unit 22. The image reading unit 22 includes the above-mentioned line sensor, a light source, and a carriage on which components of the line sensor and the light source are mounted.

In the space below the document reading surface 21, the moving unit 25 causes the image reading unit 22 to reciprocate, parallel to the document reading surface 21. The image reading unit 22 reads the image on the document while the image reading unit 22 moves in a forward direction of reciprocation, and outputs the read image as document image data.

The fixed unit 23 is fixed to the casing 26 of the moving members composed of the image reading unit 22 and the casing 26. In an embodiment, the fixed unit 23 is directly fixed to the casing 26.

The fixed unit 23 includes, for example, a processing unit for performing predetermined processing for the document image data input from the image reading unit 22, and a power source unit for feeding power to the image reading unit 22. The fixed unit 23 is located at a position at a forward direction side with respect to the image reading unit 22.

The flexible flat cable 24 is located above a flat surface 26a, which is a bottom part of the casing 26, and connects the image reading unit 22 with the fixed unit 23. A part of the flexible flat cable 24 is bent.

Using the flexible flat cable 24, the image reading unit 22 is electrically connected to the fixed unit 23.

The moving unit 25 causes the image reading unit 22 to reciprocate. The moving unit 25 includes a guide shaft 25a provided above the flat surface 26a that extends in a direction of reciprocation of the image reading unit 22, a slider 25b slidably supported by the guide shaft 25a and fixed to the image reading unit 22, a motor 25c that functions as a drive source, and a pulley 25d for transmitting torque of the motor 25c to the slider 25b.

The image reading device 2, in an embodiment, has a recessed part 27 at a backward side of the image reading unit 22 when it is in the home-position. The recessed part 27 stores the bent part 24a of the flexible flat cable 24.

The recessed part 27 extends downwardly to a lower position than the portion of the flat surface 26a of the casing 26 where the flexible flat cable 24 is located. When the image reading unit 22 is in the home-position, the recessed part 27 stores the bent part 24a of the flexible flat cable 24.

In the recessed part 27, a pair of opposing side walls 27a (guide walls) are separated from each other by a slightly larger distance than the width of the flexible flat cable 24 so that the side walls 27a function as a guide for guiding the flexible flat cable 24 into the recessed part 27.

Further, the recessed part 27 includes a bottom part 27b, an inclined part 27c that inclines from a forward direction side to the bottom part 27b, and a curved part 27d that curves from the bottom part 27b toward a connection position A between the flexible flat cable 24 and the image reading unit 22 in the home-position.

The depth of the recessed part 27 is such that the curvature of the curved part 27d corresponds to the curvature of the bent part 24a of the flexible flat cable 24 when the image reading unit 22 is located in the home-position.

In an embodiment of the image reading device 2, wherein a document is placed on the document reading surface 21, the image reading unit 22 reads an image of the document while the moving unit 22 causes the image reading unit 22 to reciprocate in a forward direction. When the image reading is completed, the image reading unit 22 is moved by the moving unit 25 in a backward direction, and returns to the home-position.

Herein, in an embodiment of the image reading device 2, the recessed part 27 is formed at a backward end of the home-position. When the moving unit 25 is located in the home-position, the bent part 24a of the flexible flat cable 24 is received in the recessed part 27.

The recessed part 27 extends downwardly with respect to the portion of the flat surface 26a of the casing 26 wherein the flexible flat cable 24 is located. Hence, compare to the situation where there is no recessed part 27, the curvature of the bent part 24a of the flexible flat cable 24 is small. Thus, the repulsive force generated by the flexible flat cable 24 can be reduced.

The flexible flat cable 24 is guided into the recessed part 27 by the side walls 27a of the recessed part 27 when the image reading unit 22 is moved in a backward direction.

Further, when the bent part 24a of the flexible flat cable 24 is received in the recessed part 27, the flexible flat cable 24 extends along the inclined part 27c and hence is gradually bent toward the bottom part 27b of the recessed part 27. Then, the bent part 24a of the flexible flat cable 24 is held by the curved part 27d.

With the image reading device 2 of the above-described embodiment, the recessed part 27 formed at the backward end of the image reading unit 22, when it is in the home-position, is bent downward at that position of the flat surface 26a at which the flexible flat cable 24 is located.

When the image reading unit 22 is located in the home-position and the bent part 24a of the flexible flat cable 24 is received in the recessed part 27, the curvature of the bent part 24a is smaller than that of a bent part 24a if there were not any recessed part 27.

Accordingly, the repulsive force that is generated the flexible flat cable 24 trying to straighten itself becomes smaller than that of a typical image reading device.

Using the image reading device 2 of this embodiment, the upward pushing force that is applied to the image reading unit 22, due to the repulsive force trying to straighten the flexible flat cable 24, can be reduced.

Also, in the image reading device 2 of this embodiment, the recessed part 27 includes opposite side walls 27a which are separated from each other by a distance corresponding to the width of the flexible flat cable 24, and which guides the flexible flat cable 24.

With the design, when the image reading unit 22 is moved in a backward direction to its home-position, the flexible flat cable 24 can be reliably guided into the recessed part 27.

In addition, in the image reading device 2 of this embodiment, the recessed part 27 includes an inclined part 27c and a curved part 27d. The depth of the recessed part 27 is determined such that the curvature of the curved part 27d corresponds to the curvature of the bent part 24a of the flexible flat cable 24 when the image reading unit 22 is located in the home-position.

Accordingly, when the bent part 24a of the flexible flat cable 24 is housed in the recessed part 27, the flexible flat cable 24 extends along the inclined part 27c and gradually bends to the bottom part 27b of the recessed part 27. Further, the bent part 24a is held by the curved part 27d.

Thus, the force applied to the flexible flat cable 24 can be minimized, and the bent part 24a can be stored in the recessed part 27.

A preferred embodiment of the present invention has been described above in detail with reference to the drawings, however, the invention is not limited to that of the embodiment, and may be modified.

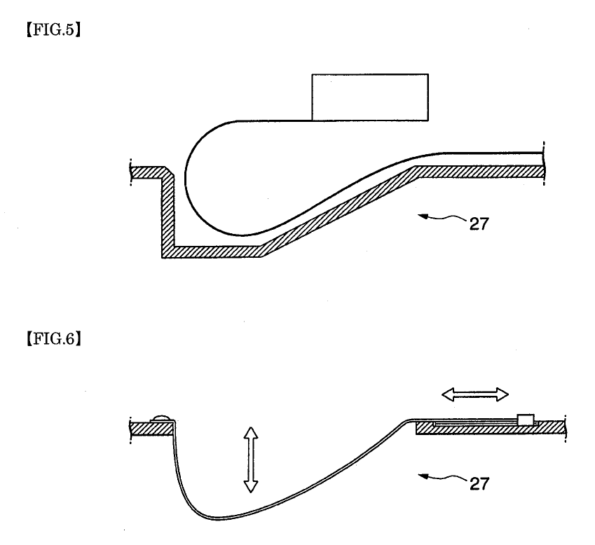

For example, the curved part 27d of the recessed part 27 in the above-described embodiment may not be provided. Referring to FIG. 5, a recessed part 27 may be formed by a plurality of flat walls.

With this design, the recessed part 27 has a larger volume than the volume of the recessed part 27 having the curved part 27d. Hence, when the operation of the moving unit 25 varies and the movement position of the flexible flat cable 24 is shifted slightly, the flexible flat cable 24 can be easily stored.

Alternatively, for example, a recessed part 27 may be formed by a flexible film member. One end of the film member may be fixed whereas another end of the film member may be slidable relative to the casing, so that the depth of the recessed part 27 is varied.

With this design, the depth of the recessed part 27 can be determined depending on the type of image reading device. A large space can be provided below the recessed part 27. Accordingly, a recording sheet can be easily taken out.

For example, in the above-described embodiment, the copier has been described as an example of an image forming apparatus to which the image reading device of the present invention is installed.

However, the present invention does not have to be installed in a copier, and may be installed in an image forming apparatus, such as a multifunction apparatus, a printer, a facsimile, and the like.

According to another embodiment, in the above-described design, the recessed part may have guide walls separated from each other by a distance corresponding to a width of the cable and guiding the cable.

According to still another embodiment, in the above-described design, the recessed part may include a bottom part, an inclined part that inclines from a forward side to a bottom part, and a curved part that curves from the bottom toward a connection position between the cable and the image reading unit in a home-position.

According to yet another embodiment, in the above-described design, the depth of the recessed part may be determined such that the curvature of the curved part corresponds to the curvature of the bent part of the cable when the image reading unit is located at the home-position.

According to another embodiment, an image forming apparatus which performs image formation includes the image reading device of the above-described design, the image reading device reading an image of a document.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. An image reading device, comprising:
an image reading unit having a home-position, reciprocates parallel to an image reading surface, and reads an image of a document placed on the image reading surface while moving in a forward direction;
a casing supporting the image reading surface such that the image reading surface defines an upper surface of the casing;
a cable fixed to the casing, located above a flat surface of the casing, and connected to the image reading unit and a fixed unit, with a part of the cable being bent, the fixed unit being electrically connected to the image reading unit; and
a recessed part extending downwardly in the image reading unit and receiving the bent part of the cable.

2. The image reading device according to claim 1, wherein the recessed part is located at a backward end with respect to the home-position, at a lower position than a position of the cable.

3. The image reading device according to claim 1, wherein the recessed part receives the bent part of the cable when the image reading unit is located in the home-position.

4. The image reading device according to claim 1, wherein the cable is a flexible flat cable.

5. The image reading device according to claim 1, wherein the recessed part has guide walls separated from each other by a distance corresponding to a width of the cable and guiding the cable.

6. The image reading device according to claim 1, wherein the recessed part includes a bottom part, an inclined part that inclines from a forward end to the bottom part, and a curved part that curves from the bottom part toward a connection position between the cable and the image reading unit in the home-position.

7. The image reading device according to claim 6, wherein a depth of the recessed part is determined such that a curvature of the curved part corresponds to a curvature of the bent part of the cable when the image reading unit is located in the home-position.

8. An image forming apparatus, comprising:
a control section designed to control the image forming apparatus;
a display operation section designed to perform an operation based on the operation by a user;
an image storage unit designed to record image data read by an image reading unit and output the read image data;
an image processing unit designed to convert the image data input from the image storage unit into print-format image data and output the print-format image data based on a control instruction input from the control section;
a print section designed perform printing on a fed recording sheet on the basis of a control instruction input from the control section; and
an image reading device fixed to a casing, wherein the image reading device includes
a casing supporting the image reading surface such that the image reading surface defines an upper surface of the casing,
the image reading unit having a home-position, reciprocates parallel to an image reading surface, and reads an image of a document placed on the image reading surface while moving in forward,
a cable fixed to the casing, located above a flat surface of the casing, and connected with the image reading unit and a fixed unit with a part of the cable being bent, the fixed unit being electrically connected to the image reading unit, and
a recessed part extending downwardly in the image reading unit and receiving the bent part of the cable.

9. A method of forming an image comprising the steps of:
reciprocating an image reading unit parallel to an image reading surface and reading an image of a document placed on the image reading surface while moving the image reading unit in a forward direction;
supporting the image reading surface on a casing such that the image reading surface defines an upper surface of the casing, a cable being fixed to the casing, located above a flat surface of the casing, and connected to the image reading unit and a fixed unit, with a part of the cable being bent, the fixed unit being electrically connected to the image reading unit; and
receiving the bent part of the cable in a recessed part extending downwardly in the image reading unit.

10. A device for forming an image comprising:
an image reading unit having a home-position, reciprocates parallel to an image reading surface and reads an image of a document placed on the image reading surface while moving in a forward direction; and
a recessed part that extends downwardly in the image reading unit and receives a bent part of the cable that electrically connects an image reading unit, when the unit is in the home position.
